(19) United States
(12) Patent Application Publication
(10) Pub. No.: US 2018/0175867 A1
(43) Pub. Date: Jun. 21, 2018

(54) SYSTEMS AND METHODS FOR CORRECTING DETERMINISTIC JITTER IN AN ALL-DIGITAL PHASE LOCKED LOOP

(71) Applicant: QUALCOMM Incorporated, San Diego, CA (US)

(72) Inventors: Emanuele Lopelli, Laguna Niguel, CA (US); Charles Wang, Irvine, CA (US); Elias Dagher, Aliso Viejo, CA (US)

(21) Appl. No.: 15/382,161

(22) Filed: Dec. 16, 2016

(51) Int. Cl. H03L 7/14; H03L 7/099

(52) U.S. Cl. CPC H03L 7/146; H03L 2207/50; H03L 7/0991

(57) ABSTRACT

A method for correcting deterministic jitter in an all-digital phase-locked loop (ADPLL) is described. The method includes determining an offset to an input frequency of the ADPLL that causes an oscillator tuning word (OTW) provided to a digitally-controlled oscillator (DCO) quantizer to fall between two DCO codes. The method also includes applying the offset to the input frequency of the ADPLL to force the DCO quantizer to have gain.

### TECHNICAL FIELD

The present disclosure relates generally to communications. More specifically, the present disclosure relates to systems and methods for correcting deterministic jitter in an all-digital phase locked loop (ADPLL).

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

Wireless communication systems are widely deployed to provide various types of communication content such as voice, video, data and so on. These systems may be multiple-access systems capable of supporting simultaneous communication of multiple wireless communication devices with one or more base stations.

Mobile devices may include a variety of circuits used during operation. For example, an oscillator may be used to synchronize various circuits across a board or integrated circuit within a mobile device. Furthermore, different circuits within a mobile device may operate using different frequencies. Therefore, mobile devices may generate multiple reference signals for different purposes.

However, like other portable electronic devices, mobile devices may have limited battery life. Along with other types of circuits, oscillators consume current during operation, thus shortening battery life. Furthermore, it may be desirable to minimize the amount of deterministic jitter produced by an oscillator. Therefore, benefits may be realized by correcting deterministic jitter in an all-digital phase locked loop (ADPLL).

### SUMMARY

A method for correcting deterministic jitter in an all-digital phase-locked loop (ADPLL) is described. The method includes determining an offset to an input frequency of the ADPLL that causes an oscillator tuning word (OTW) provided to a digitally-controlled oscillator (DCO) quantizer to fall between two DCO codes. The method also includes applying the offset to the input frequency of the ADPLL to force the DCO quantizer to have gain.

The ADPLL reacts to the offset by modulating between the two DCO codes to generate a correct average DCO code. The offset forces the ADPLL to synthesize a frequency that lies between the two DCO codes of the DCO quantizer.

Determining the offset may include calculating a DCO quantizer residue. The DCO quantizer residue may be adjusted to be a configurable fraction. The DCO quantizer residue is the difference between an unquantized OTW value and a quantized OTW value generated by the DCO quantizer. Calculating the DCO quantizer residue may include determining the difference between the unquantized OTW value at the input of the DCO quantizer and the quantized OTW value generated by the DCO quantizer. Determining the offset may also include applying a gain factor to the adjusted DCO quantizer residue.

The method may also include dynamically adjusting the offset to force a DCO quantizer residue to be at a configurable fraction under changing conditions.

An ADPLL circuit is also described. The ADPLL circuit includes a correction loop that determines an offset to an input frequency of the ADPLL that causes an OTW provided to a DCO quantizer to fall between two DCO codes. The correction loop also applies the offset to the input frequency of the ADPLL to force the DCO quantizer to have gain.

The correction loop may include a residue estimation module configured to calculate a DCO quantizer residue. The correction loop may also include an adder configured to adjust the DCO quantizer residue to be a configurable fraction. The correction loop may also include a gain factor module that applies a gain factor to the adjusted DCO quantizer residue.

The correction loop may be coupled to a loop filter, the DCO quantizer and the input of the ADPLL.

An ADPLL circuit is also described. The ADPLL circuit includes means for determining an offset to an input frequency of the ADPLL that causes an OTW provided to a DCO quantizer to fall between two DCO codes. The ADPLL circuit also includes means for applying the offset to the input frequency of the ADPLL to force the DCO quantizer to have gain.

A computer-program product for correcting deterministic jitter in an ADPLL is also described. The computer-program product includes a non-transitory computer-readable medium having instructions thereon. The instructions include code for causing a wireless communication device to determine an offset to an input frequency of the ADPLL that causes an OTW provided to a DCO quantizer to fall between two DCO codes. The instructions also include code for causing the wireless communication device to apply the offset to the input frequency of the ADPLL to force the DCO quantizer to have gain.

### BRIEF DESCRIPTION OF THE DRAWINGS

FIG. 1 is a block diagram illustrating a configuration of an all-digital phase locked loop (ADPLL);

FIG. 2 is a block diagram illustrating a configuration of an ADPLL configured for correcting deterministic jitter;

FIG. 3 is an example illustrating effects of a quantization dead-zone on the ADPLL output spectrum;

FIG. 4 is an example illustrating an unquantized oscillator tuning word (OTW) and a quantized OTW;

FIG. 5 is an example illustrating uncorrected residue behavior;

FIG. 6 is an example of quantizer gain and quantized OTW behavior when the ADPLL experiences an open-loop condition;

FIG. 7 is a flow diagram illustrating a method for correcting deterministic jitter in an ADPLL;

FIG. 8 is a block diagram illustrating a configuration of a correction loop for correcting deterministic jitter in an ADPLL;

FIG. 9 is a flow diagram illustrating another method for correcting deterministic jitter in an ADPLL;

FIG. 10 is an example illustrating the effects of correcting deterministic jitter on the ADPLL output spectrum;

FIG. 11 is an example illustrating quantized OTW with deterministic jitter correction;

FIG. 12 is an example illustrating corrected residue behavior;

FIG. 13 is an example illustrating quantizer gain after correction; and

FIG. 14 illustrates certain components that may be included within a wireless communication device.

### DETAILED DESCRIPTION

Various configurations are described with reference to the Figures, where like reference numbers may indicate functionally similar elements. The systems and methods as generally described and illustrated in the Figures could be arranged and designed in a wide variety of different configurations. Thus, the following more detailed description of several configurations, as represented in the Figures, is not intended to limit scope, but is merely representative.

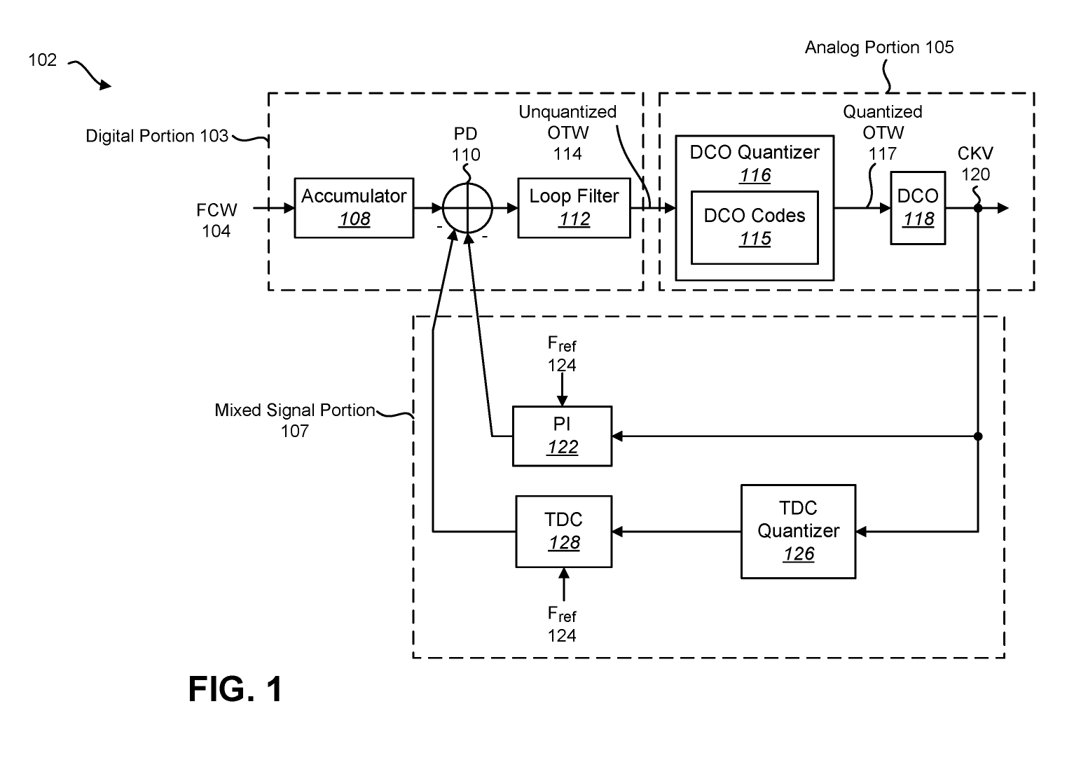

FIG. 1 is a block diagram illustrating a configuration of an all-digital phase locked loop (ADPLL) 102. The ADPLL 102 may be included in a communication device. In an implementation, the ADPLL 102 may be included in a wireless communication device.

Some wireless communication devices may utilize multiple communication technologies or protocols. For example, one communication technology may be utilized for mobile wireless system (MWS) (e.g., cellular) communications, while another communication technology may be utilized for wireless connectivity (WCN) communications. MWS may refer to larger wireless networks (e.g., wireless wide area networks (WWANs), cellular phone networks, Long Term Evolution (LTE) networks, Global System for Mobile Communications (GSM) networks, code division multiple access (CDMA) networks, CDMA2000 networks, wideband CDMA (W-CDMA) networks, Universal mobile Telecommunications System (UMTS) networks, Worldwide Interoperability for Microwave Access (WiMAX) networks, etc.). WCN may refer to relatively smaller wireless networks (e.g., wireless local area networks (WLANs), wireless personal area networks (WPANs), IEEE 802.11 (Wi-Fi) networks, Bluetooth (BT) networks, IEEE 802.15.4 (e.g., Zigbee) networks, wireless Universal Serial Bus (USB) networks, etc.).

Communications in a wireless communication system (e.g., a multiple-access system) may be achieved through transmissions over a wireless link. Such a wireless link may be established via a single-input and single-output (SISO), multiple-input and single-output (MISO) or a multiple-input and multiple-output (MIMO) system. A MIMO system includes transmitter(s) and receiver(s) equipped, respectively, with multiple (N_{T}) transmit antennas and multiple (N_{R}) receive antennas for data transmission. SISO and MISO systems are particular instances of a MIMO system. The MIMO system can provide improved performance (e.g., higher throughput, greater capacity or improved reliability) if the additional dimensionalities created by the multiple transmit and receive antennas are utilized.

A wireless communication device is an electrical device that is configured to communicate using one or more communication protocols. A wireless communication device may also be referred to as a wireless device, a mobile device, mobile station, subscriber station, client, client station, user equipment (UE), remote station, access terminal, mobile terminal, terminal, user terminal, subscriber unit, etc. Examples of wireless communication devices include laptop or desktop computers, cellular phones, smartphones, wireless modems, e-readers, tablet devices, gaming systems, keyboards, keypads, computer mice, remote controllers, headsets, smoke detectors, sensors, etc.

Phase locked loops (PLLs) may be used in circuitry for a variety of reasons, e.g., to generate stable signals at different frequencies. A PLL may be implemented as an analog or digital phase locked loop (DPLL). An all-digital phase locked loop (ADPLL) 102 has become particularly useful in wireless communication devices. ADPLLs 102 are more power efficient than analog PLLs. Furthermore, the physical size of ADPLLs 102 may be smaller than analog PLLs, which is an important consideration for portable wireless communication devices.

The ADPLL 102 may include an accumulator 108, a phase detector (PD) and a loop filter 112 in a digital portion 103. A digitally-controlled oscillator (DCO) quantizer 116 and a DCO 118 may be included in an analog portion 105 of the ADPLL 102. A phase interpolator (PI) 122, time-to-digital converter (TDC) 128 and TDC quantizer 126 may be included in a mixed signal portion 107 of the ADPLL 102. The PI 122 and the TDC 128 may be triggered by a reference frequency (F_{ref}) 124. Although not depicted, the ADPLL 102 may also include a prescaler at the output of the DCO 118 that divides the output frequency (CKV) of the DCO 118.

A frequency control word (FCW) 104 may be provided to the input of the ADPLL 102. The FCW 104 may be a digital value. In other words, the input FCW 104 is a number.

The FCW 104 may set the center frequency of the clock value (CKV) 120 generated by the DCO 118. For example, the CKV 120 may be the F_{ref} 124 multiplied by the FCW 104. The FCW 104 is supplied to a phase accumulator 108. The value by which the accumulator 108 increments on each rising edge of a clock signal is a multi-bit value of the FCW 104. The accumulation performed by the accumulator 108 essentially converts frequency to phase. If the FCW 104 input is 24, the accumulator 108 adds 24 every clock cycle (e.g., every F_{ref} 124). The output of the accumulator 108 is 24, 48, 72, etc. It is a ramp with a 24 step (in this example). It should be noted that in the case of TX data, modulation data may be injected at different points in the ADPLL 102.

A phase detector (PD) 110 subtracts the feedback phase signal values from the PI 122 and the TDC 128 from the phase signal value provided by the accumulator 108, thereby generating a phase error signal value. A loop filter 112 filters the phase error signal. The output of the loop filter 112 is a stream of digital oscillator tuning words (OTW) 114 supplied to the DCO quantizer 116.

The DCO quantizer 116 receives an unquantized digital OTW 114. The DCO 118 generates a certain frequency (referred to herein as clock value (CKV) 120) based on the DCO codes 115 of the DCO quantizer 116. The DCO quantizer 116 performs quantization on the OTW 114. The DCO quantizer 116 may quantize the OTW 114 by performing truncation or rounding of the unquantized OTW 114. This quantization produces to the DCO codes 115 provided to the DCO 118. A DCO code 115 instructs the DCO 118 to generate one of a set of discrete CKV 120 frequencies. Therefore, the DCO codes 115 of the DCO quantizer 116 correspond to steps between different output frequencies 118 of the DCO 118. The quantized OTW 117 is produced according to the DCO codes 115.

In ADPLLs 102, the loop can become opened if the inputs (i.e., unquantized OTWs 114) into DCO quantizer 116 fall between DCO codes 115. In other words, if the OTW 114 falls between quantization steps and lingers between steps for a significant amount of time, then there may be no change in DCO code 115. With the loop opened in such a manner, the deterministic, close-in phase noise and jitter of the DCO 118 does not get suppressed and quantization noise added by DCO quantizer 116 does not remain white.

Therefore, the quantization step size effectively results in a “dead-zone” for the ADPLL 102. This is similar to analog PLLS whose deterministic jitter arises, in part, because of dead-zone behavior in the phase frequency detector (PFD) and/or charge pump (CP).

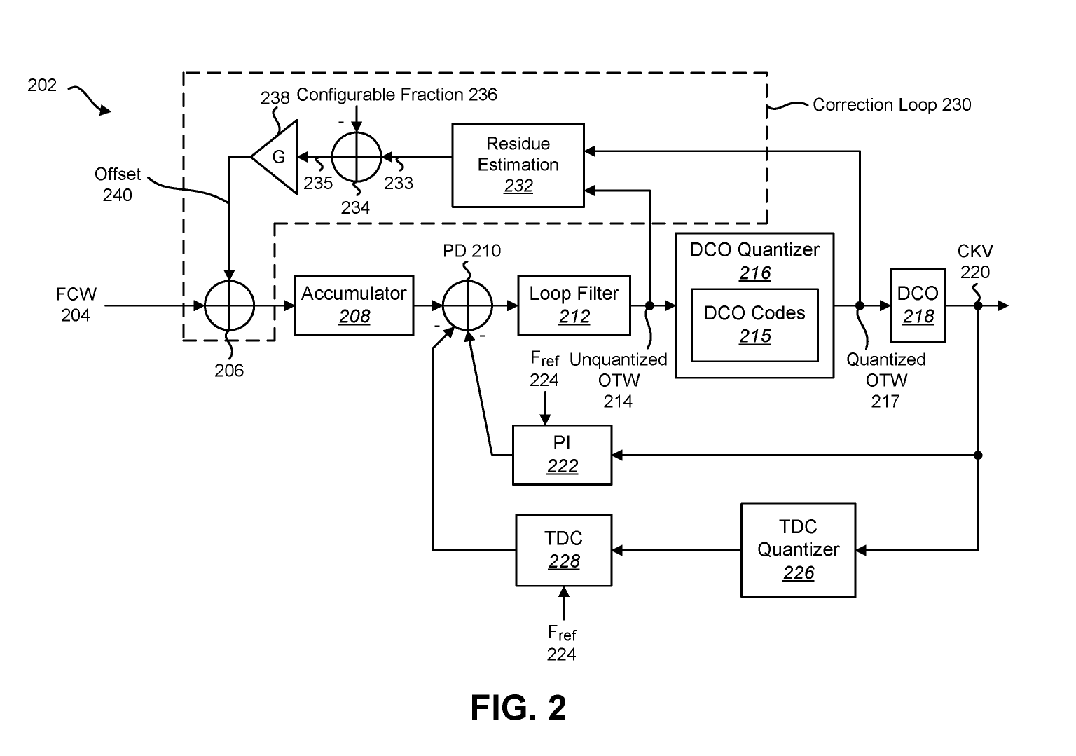

FIG. 2 is a block diagram illustrating a configuration of an all-digital phase locked loop (ADPLL) 202 configured for correcting deterministic jitter. The ADPLL 202 may be implemented in accordance with the ADPLL 102 described in connection with FIG. 1.

The ADPLL 202 may include an accumulator 208, a phase detector (PD) and a loop filter 212 in a digital portion 103. A digitally-controlled oscillator (DCO) quantizer 216 and a DCO 218 may be included in an analog portion 105 of the ADPLL 202. A phase interpolator (PI) 222, time-to-digital converter (TDC) 228 and TDC quantizer 226 may be included in a mixed signal portion 107 of the ADPLL 202 with partially digital and partially analog signals. The PI 222 and the TDC 228 may be triggered by a reference frequency (F_{ref}) 224.

As described above, the ADPLL 202 may become an open loop when the unquantized OTW 214 falls between quantization steps of the DCO quantizer 216 for a significant amount of time. In some circumstances, it is desirable to narrow the bandwidth of the loop filter 212. For example, in cases where spurious noise may be present, the bandwidth may be narrow to filter out the spurs. Additionally, it may be desirable to design the ADPLL 202 to have low noise. By reducing the noise in the ADPLL 202, the noise at the OTW 214 may be very low. The noise in the ADPLL 202 may be kept low by narrowing the bandwidth or making the analog components (e.g., DCO 218) high performance.

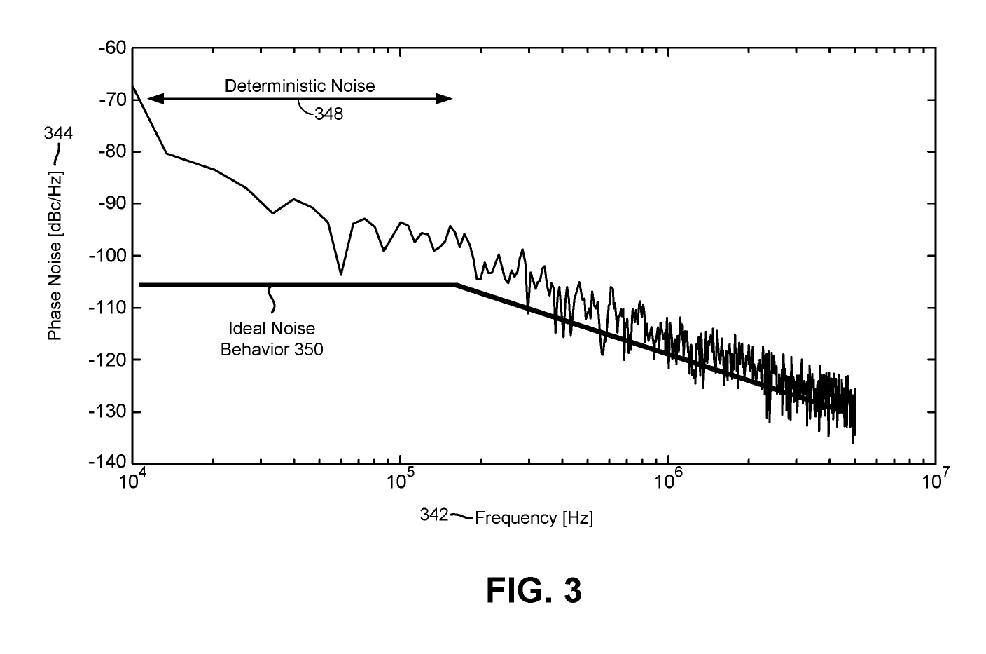

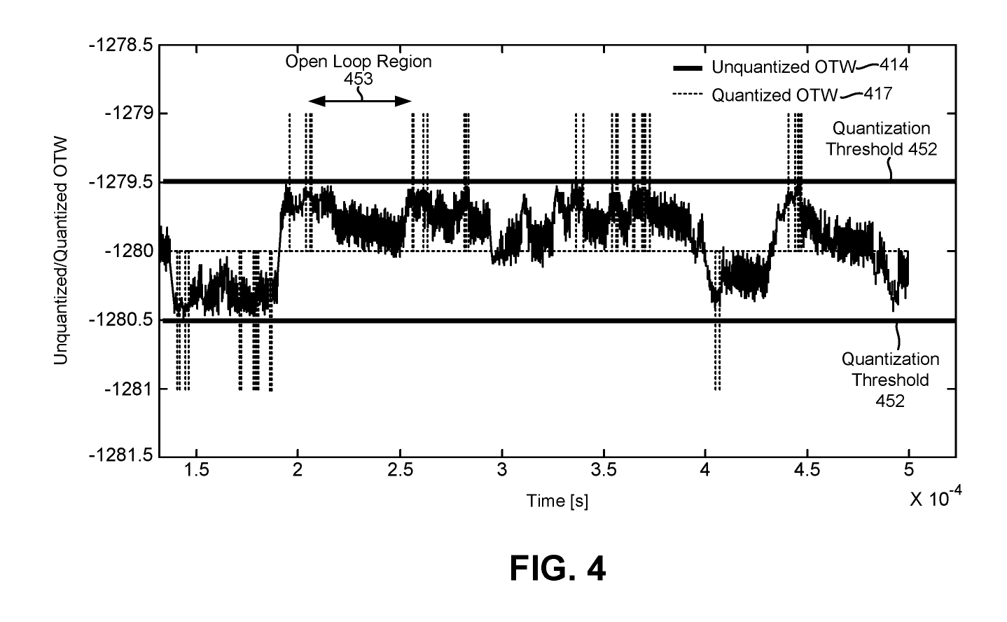

However, deterministic noise and jitter may occur when the noise of the OTW 214 becomes very low. An example of deterministic noise in the ADPLL 202 is described in connection with FIG. 3. The DCO quantizer 216 will output a certain number and always a constant number when the OTW 214 is between two thresholds, regardless of changes in the input. Therefore, if the OTW 214 error signal is very small, then the OTW 214 may remain between two thresholds. In this scenario, the DCO quantizer 216 will continue to output a constant value (i.e., the quantized OTW 217). An example of this situation is described in connection with FIG. 4.

In this case, the unquantized OTW 214 signal moves around, but the changes are so small that when the DCO quantizer 216 quantizes it, the DCO quantizer 216 generates a constant number. However, considering the fundamental operation of a PLL, a PLL will try to null the error output by the phase detector (PD) 210, and therefore, the error at the unquantized OTW 214. Inherently, the ADPLL 202 system tries to get the OTW 214 signal close to 0.

However, this is a problem with a DCO quantizer 216. When the error approaches 0, the DCO quantizer 216 output is constant. If this number is constant, the entire PLL loop can effectively be removed and replaced by a constant. In this case, nothing will change.

If a constant value is provided to the DCO 218, then there is an open-loop oscillator scenario. In this scenario, the noise at low frequency will be the noise of the DCO 218. This noise is not white noise. Instead, this is deterministic noise. The jitter is the integral of this deterministic noise. Deterministic noise and jitter are not desirable in a PLL.

In an approach to correct for deterministic noise, an ADPLL 202 may utilize a sigma-delta modulator that is added after the DCO quantizer 216. The sigma-delta modulator samples the OTW 214 at a high rate. Therefore, the sigma-delta modulator must operate at a rate much higher than the reference frequency (F_{ref}) 224. For example, the sigma-delta modulator must operate at a divided down DCO 218 frequency. This consumes a significant amount of power, which is problematic in a mobile wireless communication device.

The systems and methods described herein utilize a correction loop 230 to correct for deterministic noise and jitter. The ADPLL 202 is a continuous system that locks to a frequency. However, because the DCO 218 is quantized, it cannot synthesize any frequency that may be desired. In an example, the DCO 218 may have a step size (i.e., DCO code 215) of 100 KHz. However, to synthesize a frequency of 1 GHz plus 50 KHz, there is no code that allows that. Instead, the ADPLL 202 would jump up and down to try on average to get that value. The value at the output of the DCO quantizer 216 would jump between 2 DCO codes 215, so that on average the frequency of the PLL would be 1 GHz and 50 KHz. One DCO code 215 corresponds to 1 GHz and the other DCO code 215 corresponds to 1 GHz plus 100 KHz.

In another example, to synthesize 1 GHz plus 99 KHz, the ADPLL 202 will spend most of its time at the higher code 215 (i.e., the DCO code 215 for 1 GHz plus 100 KHz). Once in a while, the ADPLL 202 will spike down to the lower code (i.e., the DCO code 215 for 1 GHz). Because this is an average, the ADPLL 202 will synthesize 1 GHz plus 99 KHz by doing averaging. That means for most of the time, the ADPLL 202 is going to be at 1 GHz plus 100 KHz. Once in a while the ADPLL 202 will drop to 1 GHz.

The correction loop 230 may include means to calculate a residue 233 of the DCO quantizer 216. As used herein, the “residue” is the difference between the unquantized OTW 214 value and a quantized OTW 217 value generated by the DCO quantizer 216. In other words, the residue 233 is the difference between the input and the output of the DCO quantizer 216. The residue 233 may correspond to a bit (e.g., least significant bit (LSB)) of the DCO 218. Therefore, the residue 233 may vary from 0 to 1.

Referring to the earlier example, if this residue 233 is 0.5, that means the ADPLL 202 is trying to synthesize on average 1 GHz and 50 KHz. In other words, the ADPLL 202 is synthesizing in the middle of that bit of the DCO 218. In this case, the DCO quantizer 216 is going to give approximately the same number of higher DCO codes 215 and the same number of lower DCO codes 215.

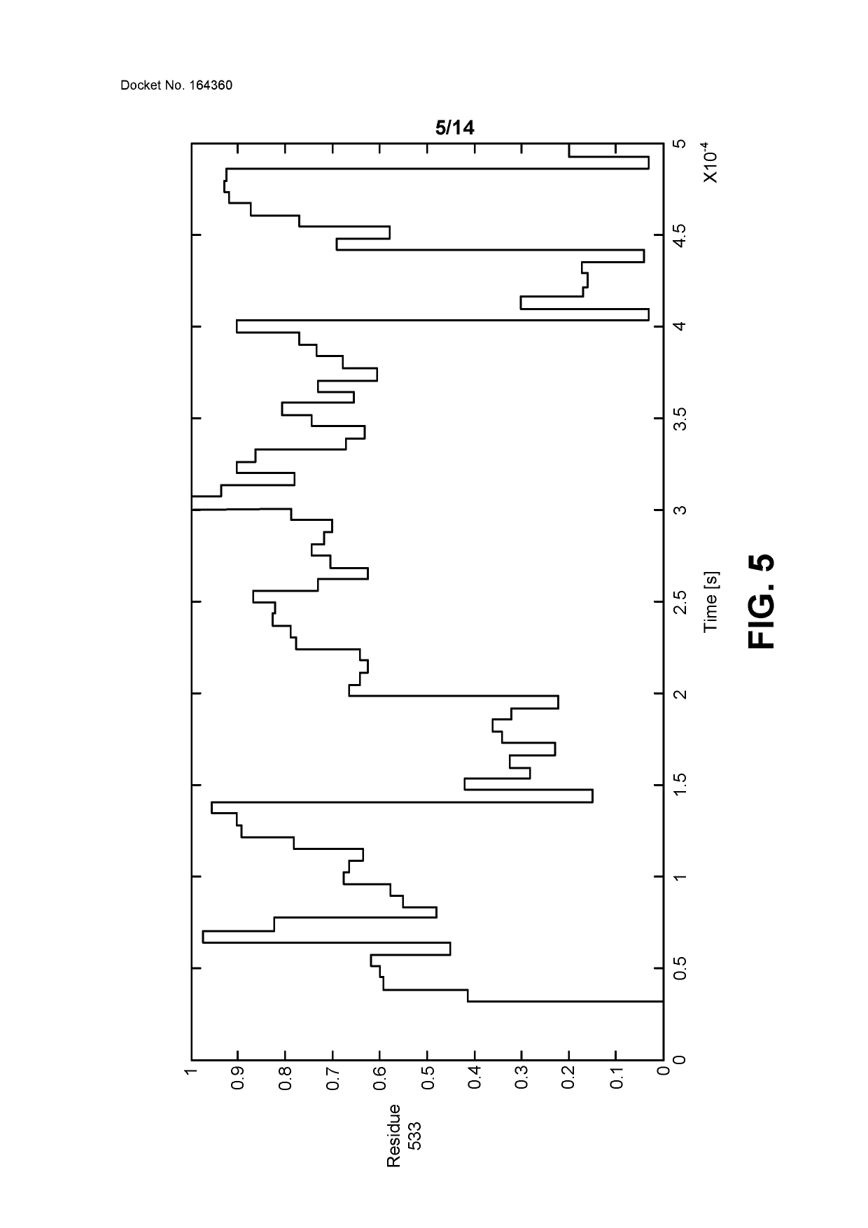

If the residue 233 gets close to 1 the DCO quantizer 216 will spend most of the time at a high DCO code 215, and once in a while decide it will go down to a low DCO code 215. When the residue 233 gets close to 0, the DCO quantizer 216 will spend most of the time at a low DCO code 215, and once in a while it will go up to a high DCO code 215. This is described in connection with FIG. 5.

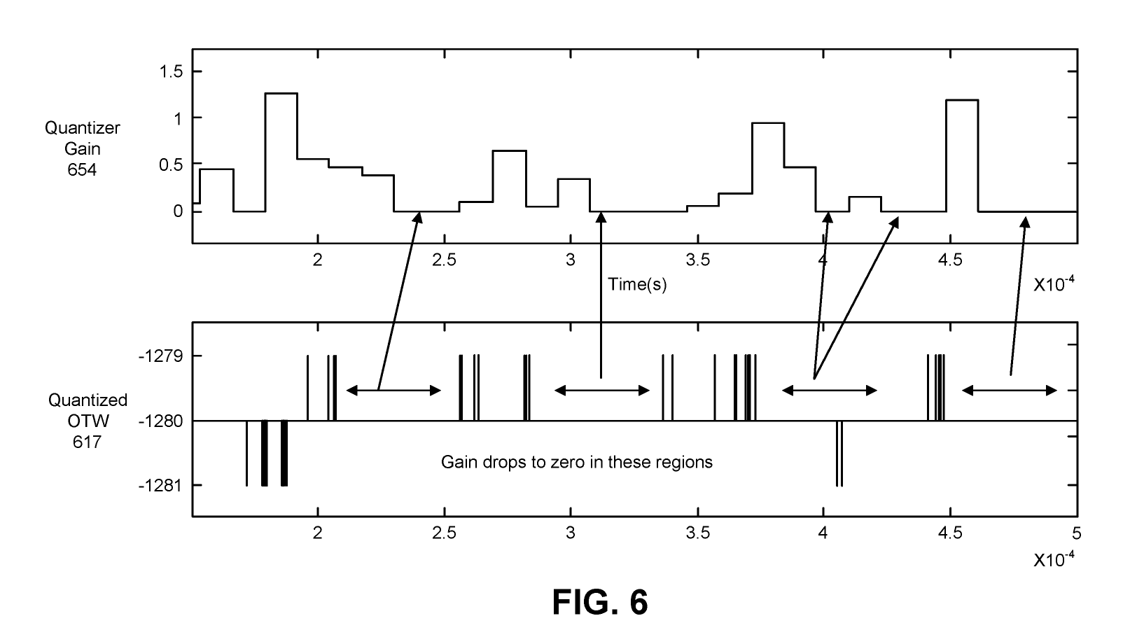

It should be noted that for correct operation of a PLL, there must be gain in the system. If the ADPLL 202 has gain, then the ADPLL 202 can correct for noise. The deterministic noise may be produced by the DCO 218. However, because this is a closed loop, if there is enough gain in the system, the ADPLL 202 will be able to follow the deterministic noise and correct for it (e.g., nullify the deterministic noise). However, if the quantized OTW 217 remains unchanged, the quantizer gain drops to 0. This scenario is described in connection with FIG. 6.

If the quantizer gain drops to 0, it is as if the loop is not there. In this case, the ADPLL 202 has no tracking capability, and cannot remove the noise. Therefore, when the quantizer gain drops to 0, that situation creates an open loop. This causes the DCO 218 to go free running, which causes a lot of low frequency noise. Therefore, the ADPLL 202 needs to be always closed by ensuring that the DCO quantizer 216 is active and has gain.

The ADPLL 202 described herein may include a correction loop 230. The correction loop 230 may ensure that the target frequency (i.e., CKV 220) is such that the OTW 214 code falls in between two DCO codes 215. In this fashion, the DCO quantizer 216 is forced to have gain.

The ADPLL 202 will react by modulating between two quantized DCO codes 215 to generate the correct average DCO code 215. In this way the OTW 214 at the input of the DCO quantizer 216 can be transferred to the output continuously. It will be dynamically encoded as a pulse width modulated (PWM) signal.

To do this, the residue 233 of the DCO quantizer 216 may be calculated. Then, the residue 233 may be adjusted to force it to be a configurable fraction 236. This may be done by using a negative feedback loop. In an implementation, the configurable fraction 236 may be 0.5. This results in the DCO quantizer 216 modulating between two DCO codes 215 approximately 50 percent of the time. The correction loop 230 may operate most efficiently when the configurable fraction 236 is approximately 0.5. As described above, deterministic noise may enter the ADPLL 202 when the residue 233 is close to 0 and close to 1. If the ADPLL 202 is forced to have a residue 233 of 0.5, the ADPLL 202 will be always active. However, the configurable fraction 236 may be any fraction between 0 and 1.

The correction loop 230 may include a residue estimation module 232. As used herein, a “module” may be implemented in hardware (e.g., circuitry), software executed by a processor or a combination of hardware and software. The residue estimation module 232 may calculate the residue 233 by determining the difference between the output and input of the DCO quantizer 216. Therefore, the residue estimation module 232 may receive the unquantized OTW 214 value and the quantized OTW 217 value generated by the DCO quantizer 216. The residue estimation module 232 can read both of these values because this is a digital PLL and the values are in the digital domain.

It should be noted that although the DCO quantizer 216 is in the analog domain, the way it creates the quantized OTW 217 is by truncation of digital words. Therefore the DCO quantizer 216 produces a digital output, which may be read by the residue estimation module 232.

The residue 233 may be provided to an adder 234, which forces the residue 233 to be around the configurable fraction 236. In an implementation, a configurable fraction 236 may be subtracted from the residue 233. For example, the adder 234 may force the calculated residue 233 to be approximately 0.5. Therefore, when the residue 233 is far from the configurable fraction 236, the adder 234 may generate an adjusted DCO quantizer residue 235 that is greater than when the residue 233 is near the configurable fraction 236. In this way, the correction loop 230 dynamically responds to changes in the ADPLL 202.

The correction loop 230 may apply a scaling factor 238 to the adjusted DCO quantizer residue 235. The scaling factor 238 may convert the adjusted DCO quantizer residue 235 from the DCO domain to the F_{ref} domain. The scaling factor 238 scales the adjusted DCO quantizer residue 235 properly so that the ADPLL 202 moves in the right direction in the right amount to produce an offset 240.

To ensure that the residue 233 is at or near the configurable fraction 236 (e.g., 0.5), the FCW 204 at the input of the ADPLL 202 may be adjusted by the offset 240 so that there is a slight offset of the center frequency with respect to the target frequency. In an implementation, an adder 206 may add the offset 240 to the FCW 204. As described above, the FCW 204 is a number that tells the ADPLL 202 at which frequency to lock. Therefore, the offset 240 moves the target frequency a small amount off the ideal position. Now the DCO 218 synthesizes a frequency CKV 220 whose DCO code 215 is between two digital values at the DCO quantizer 216.

It should be noted that the offset 240 is not a large value with respect to the target frequency. This is because one quantization level at the DCO quantizer 216 is a tiny value compared to the accuracy of the DCO 218 crystal. For example, the DCO codes 215 may cover 25 KHz. The maximum error that will be introduced by the offset 240 to force the residue 233 to the middle is half an LSB. In this example, this offset 240 is at most 12.5 KHz. Therefore, instead of synthesizing 1 GHz, the DCO 218 synthesizes 1 GHz plus 12.5 KHz.

In an implementation, this offset 240 may be dynamically adjusted at a very low rate (e.g., tens of kilohertz) in order to force the residue 233 to be at or near the configurable fraction 236 under all conditions. It should be noted that the offset 240 may be dynamically adjusted at other rates in accordance with the systems and methods described herein. For example, the correction loop 230 may apply the offset 240 after a certain number of F_{ref} 224 cycles. This will allow the ADPLL 202 to settle after applying an offset 240 before applying a newly determined offset 240. In other words, the correction loop 230 may wait for a settling period before applying a new offset 240. The added low frequency offset 240 is readily suppressed downstream, for example at the receiver side modem before demodulation occurs.

The systems and methods described herein correct the deterministic noise and jitter that is produced by the DCO 218. The noise correction is very power efficient. For example, compared to a sigma-delta modulator added after the DCO quantizer 216, the ADPLL 202 with the described correction loop 230 can run at reference frequency F_{ref} 224 rather than a divided down DCO frequency. This saves cost and improves energy efficiency.

The ADPLL 202 described herein may be used in wireless communication. The described ADPLL 202 may be cheaper and requires less energy than analog PLLs. This may be very beneficial for battery powered wireless communication devices.

FIG. 3 is an example illustrating effects of a quantization dead-zone on the ADPLL 102 output spectrum. The frequency 342 is shown with corresponding phase noise 344. Ideal noise behavior 350 is depicted. This ideal noise behavior 350 is when quantization noise of the DCO quantizer 116 can be considered white.

In principle, the ADPLL 102 has a flat area (seen in the ideal noise behavior 350) until the bandwidth. Then, the ideal noise behavior 350 follows the DCO 118. But in reality, when the DCO quantizer 116 is present, the ADPLL 102 tries to make the error (i.e., OTW 114) go to 0. After quantization, the quantized OTW 117 remains at a constant value. The quantization step size effectively results in a “dead-zone” for the ADPLL 102. This causes noise to go up. This is what an open-loop oscillator looks like. For example, an open-loop oscillator may have a slope of 20 dB going up. This portion of the noise is the deterministic noise 348. This noise is deterministic because it is the noise of the open-loop oscillator as if the loop was not there. In this case, it is as if there is no PLL anymore.

As described above, this problem can be caused by multiple reasons. For example, shrinking the bandwidth of the loop filter 112. Also, to cancel spurious signals the band may be shrunk. Additionally, in a very high performance PLL, the analog blocks that generate most of the noise are very high performing. In this case, there is not enough noise in this system to overcome the quantization by the DCO quantizer 116.

Therefore, as seen in FIG. 3, when the output of the DCO quantizer 116 remains constant, the ADPLL 102 noise 344 goes up instead of following the ideal noise behavior 350. As observed in FIG. 3, when the noise 344 is not close to the ideal noise behavior 350, then there is deterministic noise 348 coming from the DCO 118 and close-in phase noise 344 of DCO 218 is not suppressed.

FIG. 4 is an example illustrating an unquantized oscillator tuning word (OTW) 414 and a quantized OTW 417. The unquantized OTW 414 is the value at the output of the loop filter 112 that is provided to the DCO quantizer 116. The quantized OTW 417 is the output of the DCO quantizer 116.

The quantization thresholds 452 correspond to the quantization level or step. In this example, any unquantized OTW 414 that is between the quantization thresholds 452 renders −1280, which is a DCO code 115. Only when the unquantized OTW 414 passes the upper quantization threshold 452 or the lower quantization threshold 452 does the DCO quantizer 116 change to a new DCO code 115, which corresponds to the quantized OTW 417. In this example, the quantized OTW 417 generated by the DCO quantizer 116 steps between −1279, −1280 and −1281.

As seen in FIG. 4, the error signal produced by the loop filter 112 (i.e., the unquantized OTW 414) is moving. However, in many instances, the DCO code 115 (i.e., quantized OTW 417) is fixed. Therefore, the quantized OTW 417 remains at a constant value for a very large number of samples even though the PD 110 and loop filter 112 output is changing.

An open-loop region 453 is a very dangerous situation for an ADPLL 102. This means that the ADPLL 102 is open. If the DCO quantizer 116 output does not move (i.e., is constant), then the ADPLL 102 components can be removed and replaced with a constant DCO code 115. This results in deterministic noise 348 as the ADPLL 102 will follow the noise of the DCO 118. The deterministic jitter may be calculated as the integral of the deterministic noise 348.

It should be noted that there are more than one open-loop region 453 shown in FIG. 4. However, for the sake of simplicity only one open-loop region 453 was depicted.

FIG. 5 is an example illustrating uncorrected residue 533 behavior. As described above, the residue 533 is the instantaneous quantization error. In other words, the residue 533 is the difference between the output of the DCO quantizer 216 and the input of the DCO quantizer 216.

As observed in FIG. 5, when the residue 533 is uncorrected, the residue 533 has large variations. The residue 533 goes very close to zero and one least significant bit (LSB) of the ideal OTW 114.

FIG. 6 is an example of quantizer gain 654 and quantized OTW 617 behavior when the ADPLL 102 experiences an open-loop condition. In FIG. 6, the quantizer gain 654 and corresponding quantized OTW 617 are depicted over time.

In ideal conditions, a DCO quantizer 116 is assumed to have a gain 654 of 1 and its noise is white. However, this definition of quantizer gain 654 and noise behavior comes from an assumption that the signal at the DCO quantizer 116 input is large enough to cover several quantization levels. In the case of the ADPLL 102, that is not the case. The OTW 114 signal may be so small that it fits only one quantization level. This is because the phase lock loop makes the error 0. It tends to make this error signal as small as possible.

The quantizer gain 654 depends on whether there is a noise-limited regime or quantization-limited regime. In a noise-limited regime, the noise is large enough in the ADPLL 102 that the error covers several quantization levels. In a quantization-limited regime, the quantizer gain 654 is mainly limited by quantization.

The example of FIG. 6 is in a quantization-limited regime. In this case, the quantizer gain 654 depends on the statistics of the signal at the input and the output. The quantizer gain 654 may be defined as

G=Coy(input, output)/Var(input) (1)

In Equation (1), G is the quantizer gain 654, Cov (input, output) are the covariants between input and output and Var (input) are the variants of the input. The quantizer gain 654 when the input is much smaller than 1 LSB approaches 0. When the signal output (i.e., quantized OTW 617) goes to a constant value for a long time, the quantizer gain 654 drops to 0. When quantizer gain 654 approaches 0, the ADPLL 102 appears open, preventing DCO jitter from being suppressed.

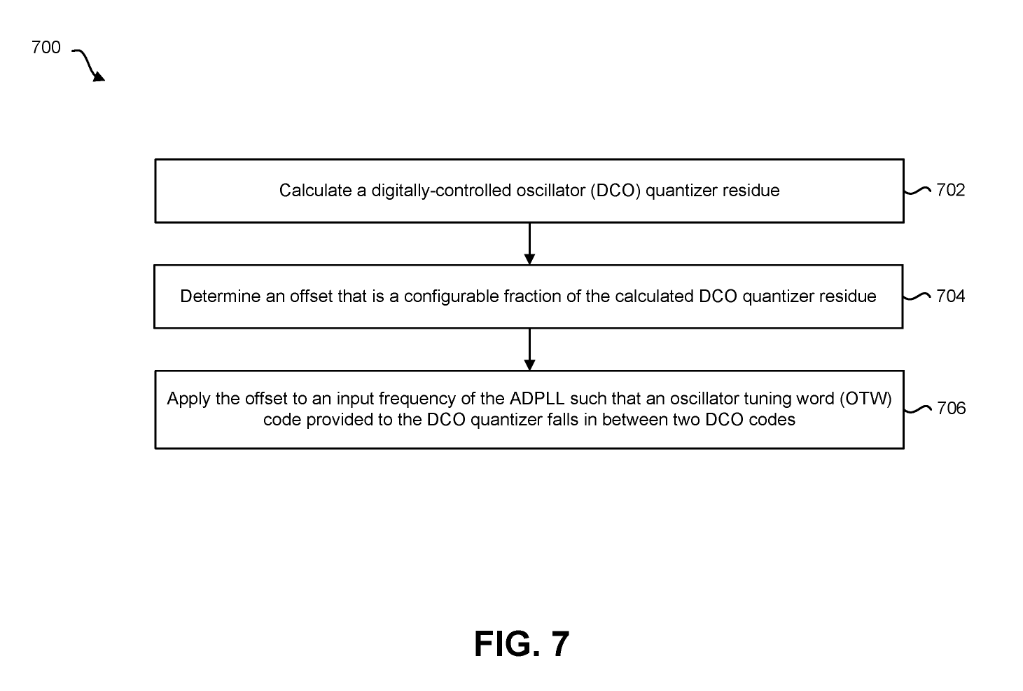

FIG. 7 is a flow diagram illustrating a method 700 for correcting deterministic jitter in an ADPLL 202. The method 700 may be performed by a correction loop 230 of the ADPLL 202. In an implementation, the correction loop 230 is coupled to a loop filter 212, a DCO quantizer 216 and the input of the ADPLL 202.

The correction loop 230 may calculate 702 a DCO quantizer residue 233. The DCO quantizer residue 233 is the difference between an unquantized OTW 214 value and a quantized OTW 217 value generated by the DCO quantizer 216. Therefore, the correction loop 230 may calculate 702 the DCO quantizer residue 233 by determining the difference between the unquantized OTW 214 value at the input of the DCO quantizer 216 and the quantized OTW 217 value generated by the DCO quantizer 216. This calculation may be performed in the digital domain.

The correction loop 230 may determine 704 an offset 240 that is a configurable fraction 236 of the calculated DCO quantizer residue 233. For example, the correction loop 230 may adjust the DCO quantizer residue 233 to be a configurable fraction 236 of the calculated DCO quantizer residue 233. In an implementation, the configurable fraction 236 may be 0.5. The configurable fraction 236 corresponds to a fraction of the least significant bit (LSB) of the DCO 218.

The correction loop 230 may also apply a scaling factor 238 to the adjusted DCO quantizer residue 235 to generate the offset 240. The scaling factor 238 may convert the adjusted DCO quantizer residue 235 from the DCO domain to the F_{ref} domain.

The correction loop 230 may apply 706 the offset 240 to an input frequency of the ADPLL 202 such that the OTW 214 code provided to the DCO quantizer 216 falls in between two DCO codes 215. The offset 240 may be applied to the FCW 204 input of the ADPLL 202.

The offset forces the ADPLL 202 to synthesize a frequency that lies between the two DCO codes 215 of the DCO quantizer 216. Because the DCO quantizer residue 233 was forced to be the configurable fraction 236, the ADPLL 202 reacts to the offset 240 by modulating between the two DCO codes 215 to generate a correct average DCO code 215 for the DCO 218. By forcing the DCO quantizer 216 to remain active, the offset 240 causes the DCO quantizer 216 to have gain 654.

The correction loop 230 may dynamically adjust the offset 240 to force the DCO quantizer residue 233 to be at the configurable fraction 236 under changing conditions. For example, the correction loop 230 may apply the offset 240 after a certain number of F_{ref} 224 cycles. This will allow the ADPLL 202 to settle after applying an offset 240 before applying a newly determined offset 240.

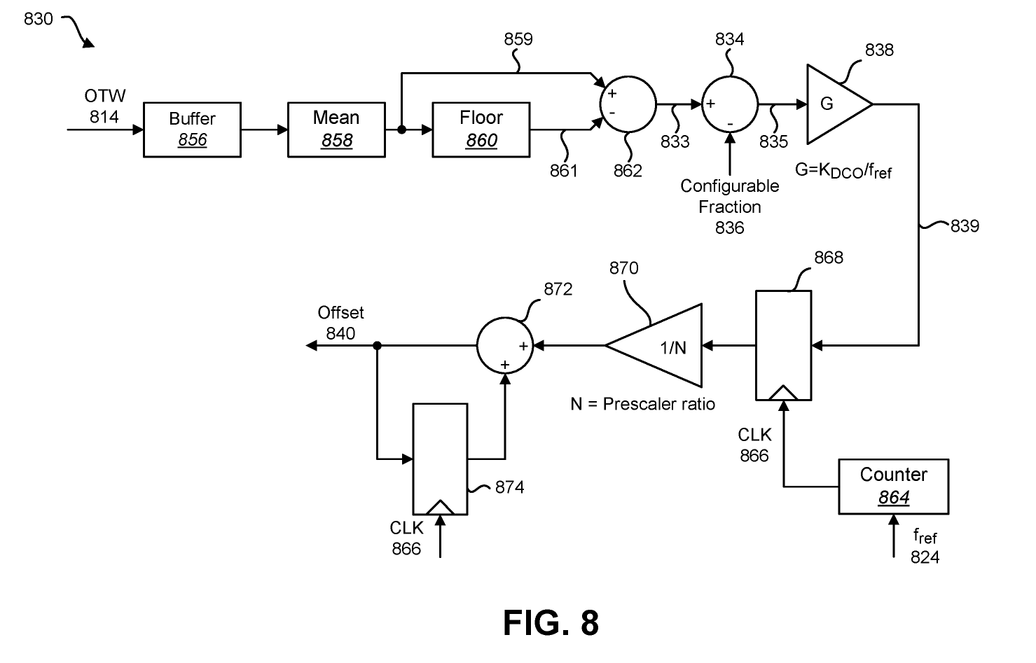

FIG. 8 is a block diagram illustrating a configuration of a correction loop 830 for correcting deterministic jitter in an ADPLL 202. The correction loop 830 may be implemented in accordance with the correction loop 230 described in connection with FIG. 2.

A certain number of unquantized OTW 814 samples may be stored in a buffer 856. For example, the buffer 856 may store two hundred fifty-six (256) samples of the unquantized OTW 814. A mean module 858 may determine the mean of the buffered OTW 814 samples. By determining the OTW mean 859, any noisy behavior in the OTW samples 814 may be normalized.

A floor module 860 may determine the floor of the buffered OTW 814 samples. In other words, the floor module 860 may determine the smallest integer value of the buffered OTW 814 samples. The floor module 860 simulates the quantization (e.g., truncation) performed by the DCO quantizer 216. An adder 862 may subtract the OTW floor 861 from the OTW mean 859 to generate the residue 833.

Another adder 834 may subtract the configurable fraction 836 from the residue 833 to generate an adjusted residue 835. In an implementation, the configurable fraction 836 is 0.5.

A scaling factor 838 may be applied to the adjusted residue 835. The scaling factor 838 may be a gain factor for the adjusted residue 835. In an implementation, the scaling factor 838 may be determined as the gain of the DCO (K_{DCO}) divided by the reference frequency F_{ref} 224.

The scaled residue 839 may be saved in a flop 868. To account for dynamic settling of the ADPLL 202, the scaled residue 839 may be sampled after a certain number of F_{ref} 224 cycles. Because there is inherently a dynamic in the ADPLL 202 system, when an offset 840 correction is applied, it takes some time for the offset 840 to develop into the output at the DCO quantizer 216. In an implementation, a counter 864 counts the F_{ref} 224 cycles. After 1,024 cycles, the counter 864 generates a CLK signal 866, which triggers the flop 868 to pass the current scaled residue 839.

The prescaler factor 870 may be applied to account for a prescalar. The scaled residue 839 may be divided by a prescalar ratio (N).

The combination of an adder 872 and flow 874 functions as an accumulator. The errors may accumulate until they converge to a certain value when the residue 833 is going to 0.5. The flop 874 may be triggered by the CLK signal 866 generated by the counter 864. The output of adder 872 is the offset 840 that is applied as a correction to the FCW 204 at the input of the ADPLL 202.

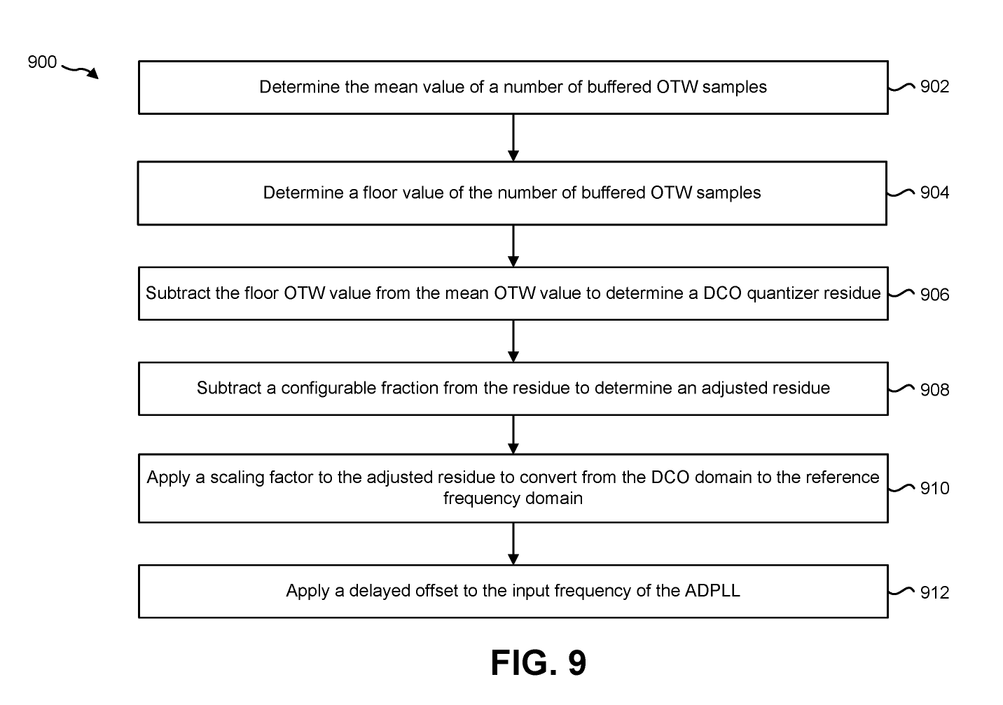

FIG. 9 is a flow diagram illustrating another method 900 for correcting deterministic jitter in an ADPLL 202. The method 900 may be performed by a correction loop 830 of the ADPLL 202. In an implementation, the correction loop 830 is coupled to a loop filter 212, a DCO quantizer 216 and the input of the ADPLL 202.

The correction loop 830 may determine 902 the mean value 859 of a number of buffered OTW samples 814. For example the correction loop 830 may sample and store 256 OTW samples 814 in a buffer. The correction loop 830 may determine 902 the mean of these 256 OTW samples 814.

The correction loop 830 may determine 904 a floor value 861 of the number of buffered OTW samples 814. For example, the correction loop 830 may determine the smallest integer value of the buffered OTW 814 samples.

The correction loop 830 may subtract 906 the floor OTW value 861 from the mean OTW value 859 to determine a DCO quantizer residue 833. The difference between the mean OTW value 859 and the floor OTW value 861 represents the difference between an unquantized OTW value 214 and a quantized OTW value 217 generated by the DCO quantizer 216 averaged over a certain number of samples.

The correction loop 830 may subtract 908 a configurable fraction 836 from the residue 833 to determine an adjusted residue 835. In an implementation, the configurable fraction 836 is 0.5.

The correction loop 830 may apply 910 a scaling factor 838 to the adjusted residue 835. The scaling factor 838 may convert the adjusted residue 835 from the DCO domain to the reference frequency (F_{ref}) 824 domain.

The correction loop 830 may apply 912 a delayed offset 840 to the input frequency 204 of the ADPLL 202. For example, the correction loop 830 may delay the scaled residue 839 a certain number of F_{ref} cycles. The correction loop 830 may then apply a prescaler factor 870 to the scaled residue 839 to generate the offset 840. The correction loop 830 may apply 912 the offset 840 to the FCW 204 of the ADPLL 202. This may be accomplished by adding the offset 840 to the FCW 204.

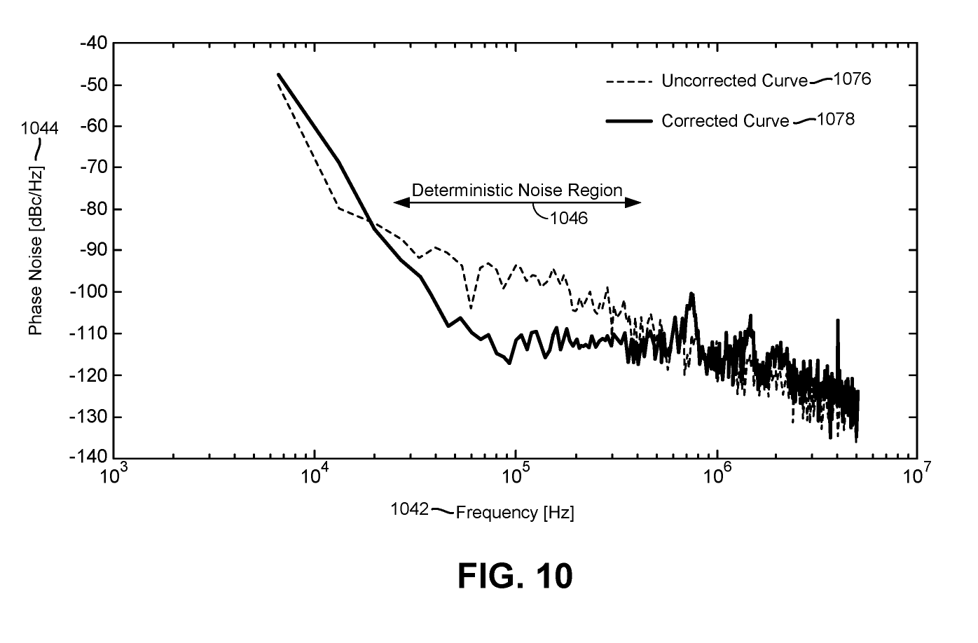

FIG. 10 is an example illustrating the effects of correcting deterministic jitter on the ADPLL 202 output spectrum. The frequencies 1042 of a corrected curve 1078 and an uncorrected curve 1076 are shown with corresponding phase noise 1044 for a 60 KHz bandwidth.

The correction loop 230 keeps the ADPLL 202 closed. This is evidenced by the lower phase noise 1044 in the deterministic noise region 1046 between 30 KHz and 200 KHz for the corrected curve 1078, as compared to a similar region in the uncorrected curve 1076. The phase noise 1044 of the corrected ADPLL 202 of FIG. 10 is much closer to the ideal noise behavior 350 as described in connection with FIG. 3. Near 10 KHz the corrected curve 1078 exhibits the low frequency offset 240 signal that is added.

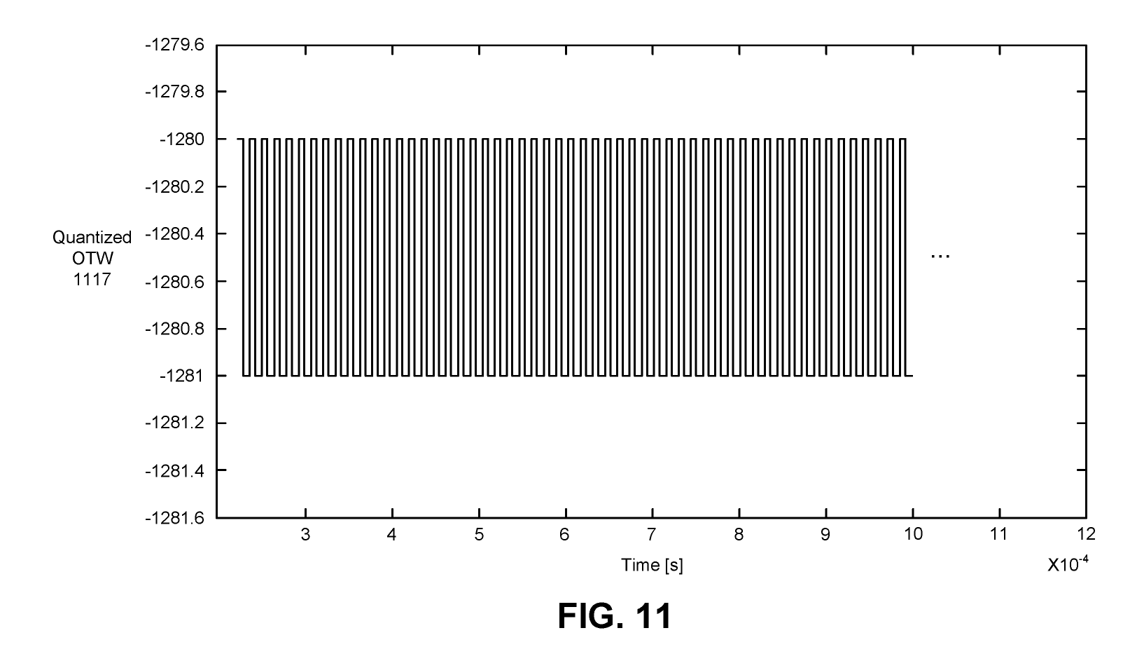

FIG. 11 is an example illustrating quantized OTW 1117 with deterministic jitter correction. The correction loop 230 generates and applies an offset 240 to the FCW 204 of the ADPLL 202 as described in connection with FIG. 2. This forces DCO quantizer 216 to modulate between two DCO codes 215 to generate a correct average quantized OTW 1117. In this example, the DCO quantizer 216 modulates the OTW 1117 between −1280 and −1281.

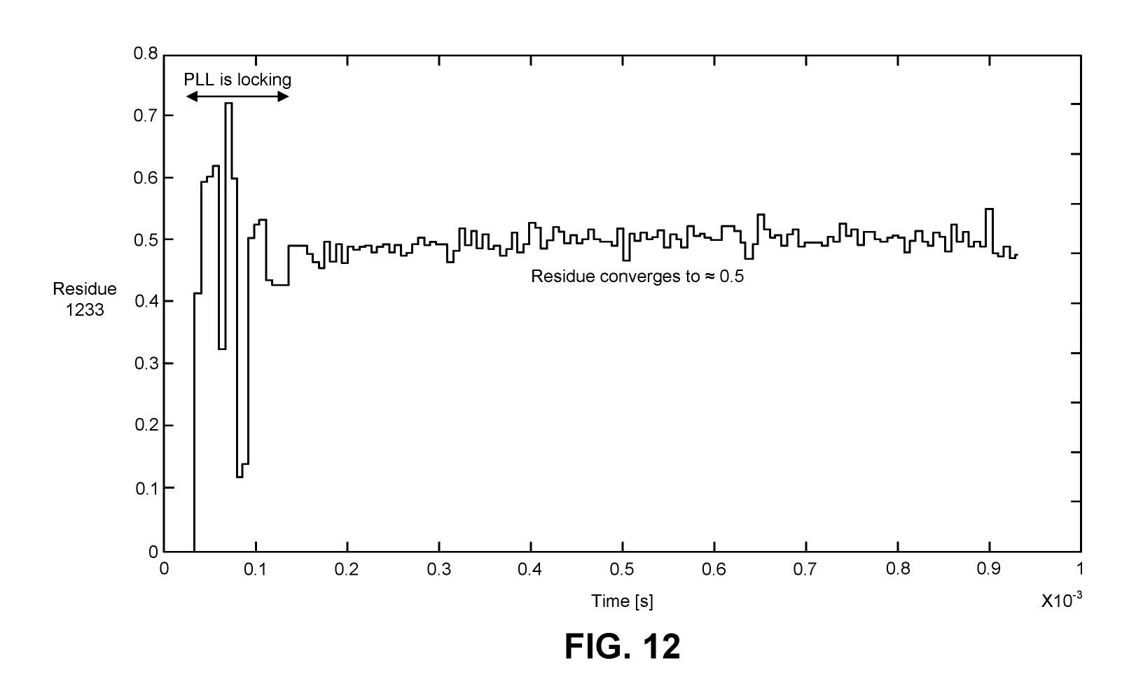

FIG. 12 is an example illustrating corrected residue 1233 behavior. The residue 1233 of the DCO quantizer 216 is plotted over time. In this example, the correction loop 230 generates and applies an offset 240 to the FCW 204 of the ADPLL 202 as described in connection with FIG. 2. This causes an OTW 214 provided to a DCO quantizer 216 to fall between two DCO codes 215.

In this example, after an initial period where the PLL is locking, the residue 1233 converges to 0.5, which is the configurable fraction 236. This may be compared to the uncorrected residue 533 behavior of FIG. 5, where the residue 533 vacillates between 1 and 0 without ever converging.

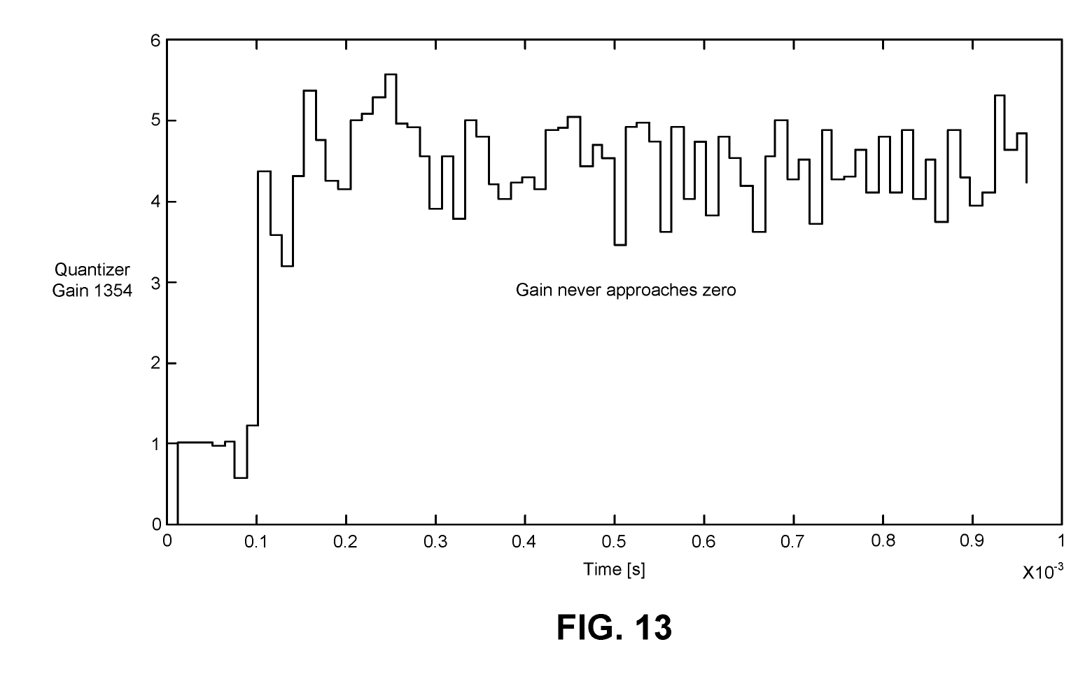

FIG. 13 is an example illustrating quantizer gain 1354 after correction. In FIG. 13, the quantizer gain 1354 is depicted over time. In this example, the correction loop 230 generates and applies an offset 240 to the FCW 204 of the ADPLL 202 as described in connection with FIG. 2. This causes an OTW 214 provided to a DCO quantizer 216 to fall between two DCO codes 215. The DCO quantizer 216 responds by modulating between the two DCO codes 215.

Because the DCO quantizer 216 remains active (i.e., the quantized OTW 217 in not constant), quantizer gain 1354 is never close to zero. Therefore, the ADPLL 202 is never opened. This may be compared to the uncorrected DCO quantizer behavior of FIG. 6, where the quantizer gain 654 approaches 0 when the DCO quantizer 216 output remains constant.

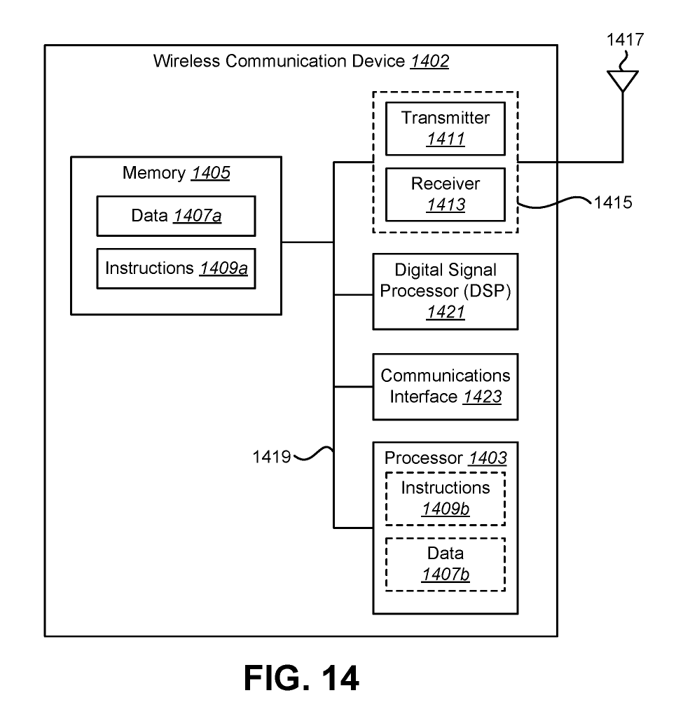

FIG. 14 illustrates certain components that may be included within a wireless communication device 1402. The wireless communication device 1402 described in connection with FIG. 14 may be an example of and/or may be implemented in accordance with the wireless communication device described in connection with one or more of FIGS. 1-13.

The wireless communication device 1402 includes a processor 1403. The processor 1403 may be a general purpose single- or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 1403 may be referred to as a central processing unit (CPU). Although just a single processor 1403 is shown in the wireless communication device 1402 of FIG. 14, in an alternative configuration, a combination of processors (e.g., an ARM and DSP) could be used.

The wireless communication device 1402 also includes memory 1405 in electronic communication with the processor 1403 (i.e., the processor can read information from and/or write information to the memory). The memory 1405 may be any electronic component capable of storing electronic information. The memory 1405 may be configured as Random Access Memory (RAM), Read-Only Memory (ROM), magnetic disk storage media, optical storage media, flash memory devices in RAM, on-board memory included with the processor, Erasable Programmable Read-Only Memory (EPROM), Electrically Erasable Programmable Read-Only Memory (EEPROM), registers and so forth, including combinations thereof.

Data 1407a and instructions 1409a may be stored in the memory 1405. The instructions 1409a may include one or more programs, routines, sub-routines, functions, procedures, code, etc. The instructions 1409a may include a single computer-readable statement or many computer-readable statements. The instructions 1409a may be executable by the processor 1403 to implement the methods disclosed herein. Executing the instructions 1409a may involve the use of the data 1407a that is stored in the memory 1405. When the processor 1403 executes the instructions 1409, various portions of the instructions 1409b may be loaded onto the processor 1403, and various pieces of data 1407b may be loaded onto the processor 1403.

The wireless communication device 1402 may also include a transmitter 1411 and a receiver 1413 to allow transmission and reception of signals to and from the wireless communication device 1402 via an antenna 1417. The transmitter 1411 and receiver 1413 may be collectively referred to as a transceiver 1415. The wireless communication device 1402 may also include (not shown) multiple transmitters, multiple antennas, multiple receivers and/or multiple transceivers.

The wireless communication device 1402 may include a digital signal processor (DSP) 1421. The wireless communication device 1402 may also include a communications interface 1423. The communications interface 1423 may allow a user to interact with the wireless communication device 1402.

The various components of the wireless communication device 1402 may be coupled together by one or more buses, which may include a power bus, a control signal bus, a status signal bus, a data bus, etc. For the sake of clarity, the various buses are illustrated in FIG. 14 as a bus system 1419.

In the above description, reference numbers have sometimes been used in connection with various terms. Where a term is used in connection with a reference number, this may be meant to refer to a specific element that is shown in one or more of the Figures. Where a term is used without a reference number, this may be meant to refer generally to the term without limitation to any particular Figure.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

It should be noted that one or more of the features, functions, procedures, components, elements, structures, etc., described in connection with any one of the configurations described herein may be combined with one or more of the functions, procedures, components, elements, structures, etc., described in connection with any of the other configurations described herein, where compatible. In other words, any compatible combination of the functions, procedures, components, elements, etc., described herein may be implemented in accordance with the systems and methods disclosed herein.

The functions described herein may be stored as one or more instructions on a processor-readable or computer-readable medium. The term “computer-readable medium” refers to any available medium that can be accessed by a computer or processor. By way of example, and not limitation, such a medium may comprise Random-Access Memory (RAM), Read-Only Memory (ROM), Electrically Erasable Programmable Read-Only Memory (EEPROM), flash memory, Compact Disc Read-Only Memory (CD-ROM) or other optical disk storage, magnetic disk storage or other magnetic storage devices, or any other medium that can be used to store desired program code in the form of instructions or data structures and that can be accessed by a computer. Disk and disc, as used herein, includes compact disc (CD), laser disc, optical disc, digital versatile disc (DVD), floppy disk and Blu-ray® disc, where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

Software or instructions may also be transmitted over a transmission medium. For example, if the software is transmitted from a website, server or other remote source using a coaxial cable, fiber optic cable, twisted pair, digital subscriber line (DSL) or wireless technologies such as infrared, radio and microwave, then the coaxial cable, fiber optic cable, twisted pair, DSL or wireless technologies such as infrared, radio and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A method for correcting deterministic jitter in an all-digital phase-locked loop (ADPLL), comprising:
determining an offset to an input frequency code word of the ADPLL that causes an oscillator tuning word (OTW) provided to a digitally-controlled oscillator (DCO) quantizer to fall between two DCO codes of the DCO quantizer, wherein determining the offset comprises calculating a DCO quantizer residue based on an unquantized OTW value and a quantized OTW value; and
applying the offset to the input frequency code word of the ADPLL to force the DCO quantizer to have gain.

2. The method of claim 1, wherein the ADPLL reacts to the offset by modulating between the two DCO codes to generate a correct average DCO code.

3. The method of claim 1, wherein the offset forces the ADPLL to synthesize a frequency that lies between the two DCO codes of the DCO quantizer.

4. The method of claim 1, wherein determining the offset comprises:
adjusting the DCO quantizer residue to be a configurable fraction.

5. The method of claim 4, wherein the DCO quantizer residue is a difference between the unquantized OTW value and the quantized OTW value generated by the DCO quantizer.

6. The method of claim 5, wherein calculating the DCO quantizer residue comprises determining the difference between the unquantized OTW value at the input of the DCO quantizer and the quantized OTW value generated by the DCO quantizer.

7. The method of claim 4, wherein determining the offset further comprises applying a gain factor to the adjusted DCO quantizer residue.

8. The method of claim 1, further comprising dynamically adjusting the offset to force a DCO quantizer residue to be at a configurable fraction under changing conditions.

9. An all-digital phase-locked loop (ADPLL) circuit, comprising:
a correction loop that determines an offset to an input frequency code word of the ADPLL that causes an oscillator tuning word (OTW) provided to a digitally-controlled oscillator (DCO) quantizer to fall between two DCO codes of the DCO quantizer, wherein determining the offset comprises calculating a DCO quantizer residue based on an unquantized OTW value and a quantized OTW value, and applies the offset to the input frequency code word of the ADPLL to force the DCO quantizer to have gain.

10. The ADPLL circuit of claim 9, wherein the ADPLL reacts to the offset by modulating between the two DCO codes to generate a correct average DCO code.

11. The ADPLL circuit of claim 9, wherein the offset forces the ADPLL to synthesize a frequency that lies between the two DCO codes of the DCO quantizer.

12. The ADPLL circuit of claim 9, wherein the correction loop comprises:
a residue estimation module configured to calculate the DCO quantizer residue; and
an adder configured to adjust the DCO quantizer residue to be a configurable fraction.

13. The ADPLL circuit of claim 12, wherein the DCO quantizer residue is a difference between the unquantized OTW value and the quantized OTW value generated by the DCO quantizer.

14. The ADPLL circuit of claim 13, wherein calculating the DCO quantizer residue comprises determining the difference between the unquantized OTW value at the input of the DCO quantizer and the quantized OTW value generated by the DCO quantizer.

15. The ADPLL circuit of claim 12, wherein the correction loop further comprises a gain factor module that applies a gain factor to the adjusted DCO quantizer residue.

16. The ADPLL circuit of claim 9, wherein the correction loop dynamically adjusts the offset to force a DCO quantizer residue to be at a configurable fraction under changing conditions.

17. The ADPLL circuit of claim 9, wherein the correction loop is coupled to a loop filter, the DCO quantizer and the input of the ADPLL.

18. An all-digital phase-locked loop (ADPLL) circuit, comprising:
means for determining an offset to an input frequency code word of the ADPLL that causes an oscillator tuning word (OTW) provided to a digitally-controlled oscillator (DCO) quantizer to fall between two DCO codes of the DCO quantizer, wherein the means for determining the offset comprises means for calculating a DCO quantizer residue based on an unquantized OTW value and a quantized OTW value; and
means for applying the offset to the input frequency code word of the ADPLL to force the DCO quantizer to have gain.

19. The ADPLL of claim 18, wherein the ADPLL reacts to the offset by modulating between the two DCO codes to generate a correct average DCO code.

20. The ADPLL of claim 18, wherein the means for determining the offset comprise:
means for adjusting the DCO quantizer residue to be a configurable fraction.

21. The ADPLL of claim 20, wherein the DCO quantizer residue is a difference between the unquantized OTW value and the quantized OTW value generated by the DCO quantizer.

22. The ADPLL of claim 21, wherein the means for calculating the DCO quantizer residue comprise means for determining the difference between the unquantized OTW value at the input of the DCO quantizer and the quantized OTW value generated by the DCO quantizer.

23. The ADPLL of claim 20, wherein the means for determining the offset further comprise means for applying a gain factor to the adjusted DCO quantizer residue.

24. The ADPLL of claim 18, further comprising means for dynamically adjusting the offset to force a DCO quantizer residue to be at a configurable fraction under changing conditions.

25. A computer-program product for correcting deterministic jitter in an all-digital phase-locked loop (ADPLL), the computer-program product comprising a non-transitory computer-readable medium having instructions thereon, the instructions comprising:
code for causing a wireless communication device to determine an offset to an input frequency code word of the ADPLL that causes an oscillator tuning word (OTW) provided to a digitally-controlled oscillator (DCO) quantizer to fall between two DCO codes of the DCO quantizer, wherein the code for causing the wireless communication device to determine the offset comprises code for causing the wireless communication device to calculate a DCO quantizer residue based on an unquantized OTW value and a quantized OTW value; and
code for causing the wireless communication device to apply the offset to the input frequency code word of the ADPLL to force the DCO quantizer to have gain.

26. The computer-program product of claim 25, wherein the ADPLL reacts to the offset by modulating between the two DCO codes to generate a correct average DCO code.

27. The computer-program product of claim 25, wherein the code for causing the wireless communication device to determine the offset comprises:
code for causing the wireless communication device to adjust the DCO quantizer residue to be a configurable fraction.

28. The computer-program product of claim 27, wherein the DCO quantizer residue is a difference between the unquantized OTW value and the quantized OTW value generated by the DCO quantizer.

29. The computer-program product of claim 28, wherein the code for causing the wireless communication device to determine the offset further comprises code for causing the wireless communication device to apply a gain factor to the adjusted DCO quantizer residue.

30. The computer-program product of claim 25, further comprising code for causing the wireless communication device to dynamically adjust the offset to force a DCO quantizer residue to be at a configurable fraction under changing conditions.
